(19) United States
(12) Patent Application Publication
(10) Pub. No.: US 2005/0040459 A1
(43) Pub. Date: Feb. 24, 2005

(54) Method and structure for improving the gate resistance of a closed cell trench power MOSFET

(76) Inventors: John E. Amato, Tracy, CA (US); Badredin Fatemizadeh, San Jose, CA (US); Ali Salih, Mesa, AZ (US); Shamsul A. Khan, Santa Clara, CA (US)

Correspondence Address: QUARLES & BRADY LLP, RENAISSANCE ONE, TWO NORTH CENTRAL AVENUE, PHOENIX, AZ, 85004-2391, US

(21) Appl. No.: 10/647,029

(22) Filed: Aug. 22, 2003

(51) Int. Cl. H01L 29/76

(52) U.S. Cl. 257/330

(57) ABSTRACT

A closed cell trench power MOSFET has a trench (54) running in first and second perpendicular directions through a body region (48) and extending into an epitaxial region (46). The trenches meet to form intersections (16). A polysilicon layer (58) is deposited in the trench. A photoresist pattern (60) is formed over the intersections to inhibit removal of the conductive material from the trench in and around the intersection areas. The process of inhibiting removal of the conductive material over the intersection areas of the trench prevents formation of a depression in the polysilicon in and around the intersection which would increase resistivity in the gate region. The goal of preventing formation of depressions in the polysilicon can also be achieved by making the polysilicon thicker on the intersections prior to the etching process and by making the trenches narrower in and around the intersections.

### FIELD OF THE INVENTION

The present invention relates in general to semiconductor devices and, more particularly, to a method and structure for improving the gate resistance of a closed cell trench power MOSFET.

### BACKGROUND OF THE INVENTION

Metal oxide semiconductor field effect transistors (MOSFETs) are commonly used in power transistor applications such as power supplies, power converters, energy systems, telecommunications, motor control, automotive, and consumer electronics. Power devices generally refer to transistors and other semiconductor devices that can switch about 1.0 ampere or more of conduction current. Power MOSFETs are well known as high input impedance, voltage controlled devices which require only a small charge to initiate turn-on from relatively simply drive circuitry. Power MOSFETs exhibit high drain to source current carrying capacity, low drain to source resistance (R_{DSon}) to reduce conduction losses, high switching rate with low switching losses, and high safe operating range (SOA) which provides the ability to withstand a combination of high voltage and high current.

One electrical characteristic of the power MOSFET is its gate resistance (R_{g}). To turn on a power MOSFET, a certain charge must be applied to the gate to raise its potential to a threshold level. The R_{g} is generally defined as the impedance which an applied gate to source voltage (V_{GS}) must overcome to establish a sufficient charge on the gate of the MOSFET to initiate conduction through the channel between the drain and source regions. The greater the gate resistance, the longer the time needed for a given V_{GS} to overcome the gate resistance (and gate capacitance) and turn on the power MOSFET. Conversely, the smaller the gate resistance, the shorter the time needed for a given V_{GS} to overcome the gate resistance and turn on the power MOSFET. Thus, the gate resistance directly effects the turn-on time and switching rate of the power MOSFET. In most power applications, a shorter turn-on time and higher switching speed is preferable.

Power MOSFETs can be constructed with any one of several semiconductor topologies. One common semiconductor topology used to manufacture power MOSFETS is known as a vertical trench technology. A vertical trench design generally includes source regions formed in a body region on either side of a trench which is lined with silicon dioxide and filled with polysilicon. The polysilicon operates as the gate region. The drain region is formed below an epitaxial layer separating the source and drain regions. An applied V_{GS} charges a channel adjacent to the vertical trench wall and creates a conduction path down between the source region and drain region.

The trenches can be formed in a variety of patterns. In a stripe trench design, the trenches are formed as a plurality of parallel stripes running one direction across the surface area of the power MOSFET. In a closed cell trench design, the trenches run as a plurality of parallel stripes in two directions along the length and width of the surface area of the power MOSFET. The length-wise stripes and the width-wise stripes are perpendicular to one another in the plane of the silicon and form intersections or junctions as they cross, creating a mesh or cell-array pattern. The closed cell trench is continuous across the power MOSFET surface area.

The closed cell trench power MOSFET operates as a plurality of transistors each conducting a proportionate amount of the overall drain to source current flowing through the device. A gate bus is routed around the perimeter of the power MOSFET and provides V_{GS} to the gate region of each of the plurality of transistors. The effective R_{g} of each transistor depends, in part, on its location relative to the gate bus. Transistors in the center of the device, farthest away from the gate bus, tend to have a higher R_{g} because of the longer conduction paths from the gate bus to the gate regions of the individual transistors. Again, the higher R_{g} delays the turn-on time and reduces the switching rate of the power MOSFET. Furthermore, depending on the values of V_{GS} and R_{g}, some transistors in the center of the substrate may turn on only partially, or not at all, which overloads other transistors in the cell-array or lowers drain to source current capacity and increases R_{DSon}.

In general, increasing cell density, i.e. number of cells per unit area, reduces gate resistance because with the greater number of cells comes an increase in the number of shorter conduction paths from the gate bus to the gate regions of the individual transistors. A closed cell trench design has more transistors per unit area and more gate bus to gate region conduction paths than a stripe design with comparative pitch. Yet the closed cell trench design has a greater gate resistance than comparative pitch stripe designs. The closed cell designed gate resistance decreases with increased cell density (also true for stripe design). However, when compared with stripe technology, with the same cell pitch, closed cell technology gives a higher gate resistance.

A need exists to avoid increasing gate resistance when using closed cell designs.

### SUMMARY OF THE INVENTION

In one embodiment, the present invention is a method of manufacturing a closed cell trench semiconductor device comprising the steps of forming a drain region, depositing an epitaxial region over the drain region, forming a body region over the epitaxial region, forming a trench in first and second directions through the body region and extending into the epitaxial region, wherein the trench in the first direction and the trench in the second direction cross to form an intersection, depositing a conductive material in the trench, and forming a protective layer over the intersection to inhibit removal of the conductive material from the trench in and around the intersection.

In another embodiment, the present invention is a semiconductor device, comprising a drain region and an epitaxial region disposed over the drain region. A body region is disposed over the epitaxial region. A trench runs in first and second directions through the body region and extending into the epitaxial region. The trench in the first direction and the trench in the second direction cross to form an intersection. A conductive material is deposited in the trench. A protective layer formed over the intersection inhibits removal of the conductive material from the trench in and around the intersection.

### BRIEF DESCRIPTION OF THE DRAWINGS

FIG. 1 is a top view of a closed cell trench semiconductor device;

FIG. 2 illustrates an intersection between length-wise stripes and width-wise stripes;

FIG. 3 is a cross-sectional view of the closed cell trench semiconductor device taken at an intersection;

FIG. 4 is a cross-sectional view of the semiconductor device of FIG. 3 with a photoresist pattern over the trench;

FIG. 5 is a cross-sectional view of the semiconductor device of FIG. 3 following removal of the photoresist pattern over the trench; and

FIG. 6 illustrates as an intersection with narrowing width across the trench.

### DETAILED DESCRIPTION OF THE DRAWINGS

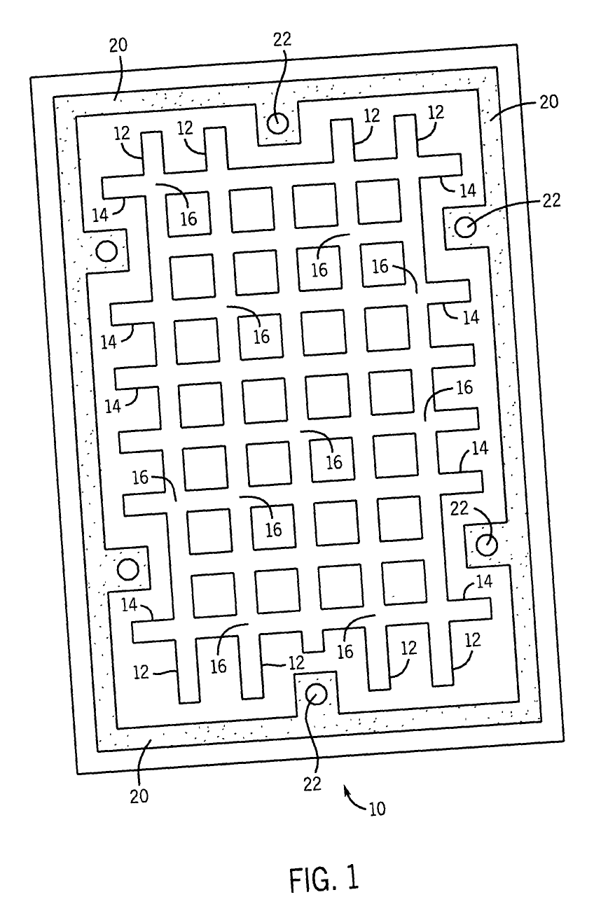

Referring to FIG. 1, a top view of semiconductor device 10 is shown suitable for silicon-based semiconductor manufacturing processes. Semiconductor device 10 is generally useful and applicable to insulated gate transistors and devices, including MOSFETs, insulted gate field effect transistors (IGFETs), insulated gate bipolar transistors (IGBTs), and MOS-controlled thyristors. Semiconductor device 10 is particular applicable to power semiconductor devices, i.e. devices that can switch about 0.5 to 1.0 amperes or more conduction current with an applied drain voltage between 5 volts and hundreds of volts. A typical applied gate voltage ranges between 1 and 20 volts. A power MOSFET is one type of power semiconductor device and exhibits high drain to source current carrying capacity, low R_{DSon} to reduce conduction losses, high switching rate with low switching losses, and high SOA which provides the ability to withstand a combination of high voltage and high current. In other embodiments, semiconductor device 10 may be formed using gallium-arsenide processes to produce junction field effect transistors (JFETs) and metal semiconductor field effect transistors (MESFETs). Semiconductor device 10 may be formed using silicon germanium processing technology. Some of the applications for power semiconductor devices include power supplies, power converters, energy systems, telecommunications, motor control, automotive, and consumer electronics.

Semiconductor device 10 shown in the figures is not necessarily drawn to scale for purposes of illustration and may differ in relative proportions in practice. In the figures, common reference numerals are used for elements which provide the same or similar function.

Semiconductor device 10 is manufactured using a closed cell trench design. FIG. 1 is a simplified top view of a close cell trench semiconductor device 10 including a plurality of stripes 12 running in a length-wise direction and a plurality of stripes 14 running in a width-wise direction. Stripes 12 and 14 represent the trench of semiconductor device 10 containing the gate region. Stripes 12 run parallel having a width in a range of 0.1 to 1.0 microns and a separation or pitch between stripes of about 1.0 to 5.0 microns. Stripes 14 run parallel to one another and perpendicular to stripes 12 and have a width of 0.1 to 1.0 microns and a stripe separation of 1.0 to 5.0 microns. In the final product, semiconductor device 10, having a die size of about 3.0 mm by 3.0 mm, contains approximately 1 million cells depending on cell density.

In a closed cell trench topology, an intersection or junction 16 is formed as each stripe 12 meets or crosses with a perpendicular stripe 14. Semiconductor device 10 has a large number of intersections 16. With stripes 12 and 14 meeting at intersections 16, the trench becomes continuous across semiconductor device 10.

Gate bus 20 is a metalization layer which substantially surrounds the perimeter of semiconductor device 10 and includes gate pads 22 disposed at regular intervals for wire bonding to an external lead to receive a gate voltage V_{GS}. Portions of gate bus 20 extend inwards on one or more layers (not shown) to make contact with the gate regions.

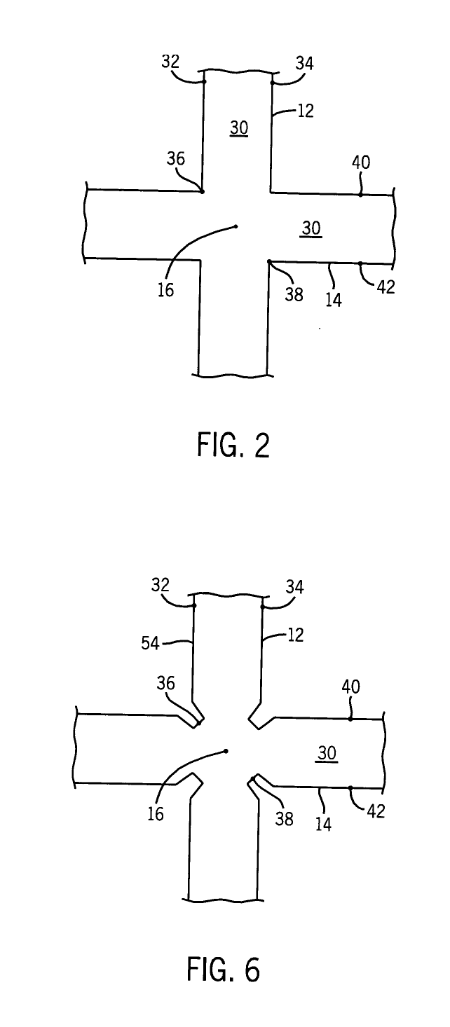

The intersection 16 between stripe 12 and stripe 14 is enlarged in FIG. 2. The area enclosed by stripes 12 and 14, including intersection 16, represents the trench and forms gate region 30 of semiconductor device 10. It is important to note that the width of stripe 12 between points 32 and 34, which is away from intersection 16, is less than the distance across intersection 16 as measured between points 36 and 38. Likewise, the width of stripe 14 between points 40 and 42, which is away from intersection 16, is less than the distance across intersection 16 as measured between points 36 and 38. Accordingly, the effective width of gate region 30 is greater in and around intersection 16, e.g. between points 36 and 38, than the non-intersection portions of stripes 12 and 14, e.g. between points 32-34 and 40-42. In addition, the surface area in and around intersection 16 is greater than non-intersection areas of stripes 12 and 14.

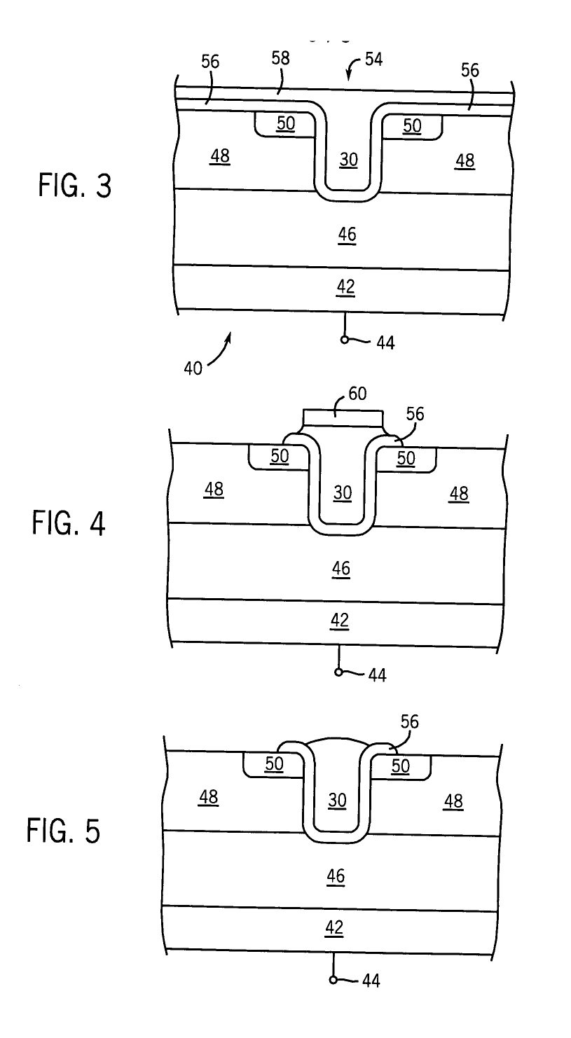

Turning to FIG. 3, a cross-sectional view of a vertical power MOSFET 40 is shown following several manufacturing process steps. The cross-sectional view of MOSFET 40 is cut across intersection 16 between points 36 and 38 of FIG. 2. Although MOSFET 40 is shown as an n-channel device, fabrication of p-channel device would follow directly. Drain region or layer 42 is formed in a silicon-based substrate to operate as the drain of MOSFET 40. Electrode or terminal 44 provides electrical contact to drain region 42. Drain region 42 is doped to have an n-type conductivity with high doping concentration, on the order of 10¹⁹ atoms arsenic/centimeter (cm)³, to provide a low electrical resistance to current flow. Epitaxial region or layer 46 is disposed on drain region 42. Epitaxial region 46 has an n-type conductivity with a lighter doping concentration, on the order of 10¹⁶ atoms phosphorus/cm³. Body region or layer 48 is formed on epitaxial region 46 and doped with p-type material, for example 10¹⁷ atoms boron/cm³. Source region 50 is heavily doped to be n-type conductivity and operates as the source of MOSFET 40. N-type dopants are diffused in source region 50 to a depth of about 0.5 micrometers with a concentration of about 10²⁰ atoms arsenic/cm³ to provide a low resistance to current flow.

A masking layer is applied over MOSFET 40 with an opening in the masking layer to form trench 54. Trench 54 is etched through the opening in the masking layer to a depth of about 3.0 microns and a width of about 1.0 microns. Trench 54 can be formed using a reactive ion etch process. Trench 54 extends about 0.2 microns into epitaxial region 46. A blanket oxide layer 56, such as silicon dioxide or silicon nitride, is disposed as a dielectric material over body region 48, source region 50, and fills trench 54 to a thickness of about 200 to 1000 Angstroms. A polysilicon layer 58 is applied over oxide layer 56 to fill trench 54. Polysilicon layer 58 is a heavily doped phosphorous conductive material, on the order 10 ohms per square, to provide a low gate resistance of 1 to 2 ohms. Polysilicon layer 58 forms gate region 30 in trench 54. Metal silicide is another conductive material that can be used to form gate region 30 in trench 54.

In the prior art, polysilicon layer 58 is etched back to a level substantially even with the top of trench 54. In the non-intersection areas of trench 54, e.g. between points 32 and 34 or points 40-42, the polysilicon is substantially level with the top of trench 54. In and around intersection 16, the polysilicon is depressed or sunken. In other words, around the edges of intersection 16, the polysilicon is substantially level with the top of trench 54, while near the center of intersection 16, the polysilicon is sunken below the top of trench 54.

As discussed for FIG. 2, intersection 16 of trench 54 has a larger surface area than the non-intersection areas. There is a larger overall area over intersection 16 on which to deposit polysilicon as compared to the non-intersection areas of trench 54. The larger surface area of the trench at the intersection causes the initial polysilicon deposition height to be lower than the non-intersection areas of the trench. Given an equal etch rate and equal etch time, the larger surface area in and around intersection 16 would cause polysilicon layer 58 to be etched back to a greater extent than would occur in the non-intersection areas of trench 54. The larger surface area of intersection 16 would result in an over-etch of the polysilicon in the respective areas. The height or thickness of the polysilicon in and around the intersection, particularly near the center of the intersection, would be lower than in non-intersection areas.

In the background, a paradox is noted that a closed cell trench design, while having more transistors per unit area and more gate bus to gate region conduction paths, also has a greater gate resistance than comparative pitch stripe designs. The increased gated resistance of the closed cell with respect to the stripe design may be attributed to the above noted depressions in the polysilicon in and around intersections 16. The depressions or reduction in thickness of the polysilicon in and around intersections 16 increases the resistivity in gate region 30 and restricts the charge applied to the channel region of MOSFET 40. The greater the cell density, the greater the number of intersections and the greater the effective gate resistance for the semiconductor device, which is an undesirable result.

Turning to FIG. 4, a cross-sectional view of MOSFET 40 is shown following additional manufacturing process steps. A photoresist pattern 60 is placed over polysilicon layer 58 in and around intersections 16. Photoresist pattern 60 forms a protective layer to inhibit or prevent removal of the underlying polysilicon. However, photoresist pattern 60 is not placed over polysilicon layer 58 on the non-intersection areas of trench 54. A reactive ion etch is applied to the surface of semiconductor 10 to remove portions of polysilicon layer 58. When polysilicon layer 58 is etched back, the polysilicon material over the non-intersection areas is substantially level with the top of trench 54. Yet, during the same etch back process, photoresist pattern 60 over intersections 16 prevents or slowdowns the etching process in and around the respective areas. When photoresist pattern 60 is removed, the polysilicon over intersections 16 is at least substantially level with the top of trench 54 over the entire surface area of intersection 16 as shown in FIG. 5. If the etch rate under photoresist pattern 60 is slowed down enough, or effectively inhibited, the polysilicon may appear as a bump, slightly above or over each intersection 16. Depending on the coverage of photoresist pattern 60, the polysilicon may overlap the edges of trench 54. The polysilicon material forming gate region 30 in and around intersection 16 is no longer depressed or sunken which could cause the undesired increase in resistivity and gate resistance with closed cell designs.

By depositing photoresist over polysilicon layer 58 and masking intersections 16, a hard mask is formed over the intersection 16 to slow or inhibit the etching process in the respective areas. As a result, the polysilicon material in and around intersections 16 is devoid of any depressions or reduction in thickness. The polysilicon material over intersection 16 is at least substantially level with or slightly above the top of trench 54 over the entire surface area of intersection 16. The additional thickness of polysilicon over intersection 16 reduces the resistivity in gate region 30 as compared to prior art closed cell trench designs where depressions are formed in and around the intersections as described above. Accordingly, the gate resistance of power MOSFET 40 manufactured with a closed cell trench process as described herein reduces with increasing cell density as desired. Thus, the gate resistance can be reduced to approach that of a comparable pitch stripe design and achieve even lower values.

In an alternate embodiment, the depressions in the gate regions in and around the intersections can be avoided by depositing additional polysilicon over intersections 16. The polysilicon material over the non-intersection areas of trench 54 has a first thickness above trench 54. When etched back, the polysilicon comes to a level substantially even with the top of the trench. The polysilicon material over the intersection areas of trench 54 will have a second thickness greater than the thickness of the polysilicon over the non-intersection areas. Given the same etch rate and same etch time, the greater thickness polysilicon over intersections 16 will still etch back to a level substantially even with or slightly above the top of trench 54 over the entire surface area of intersection 16.

The additional polysilicon over intersection 16 can be applied in a two step process. A first layer of polysilicon is disposed evenly across all of stripes 12 and 14 of MOSFET 40, including intersections 16. A second layer is then deposited over intersections 16 with a masking pattern. The result is an extra thickness of polysilicon over intersections 16, which when etched back, still maintains the polysilicon at least to a level substantially even with or slightly above the top of trench 54.

In yet another embodiment, the depressions in the gate regions in and around the intersections can be avoided by narrowing the effective width of intersection 16 to be substantially the same as the width of the non-intersections areas of the trench. As shown in FIG. 6, the width across trench 54 narrows at intersection 16. The distance between points 36 and 38 in FIG. 6 is made to be approximately the same as the distance between points 32-34 and 40-42. The trench is made substantially the same width in the intersection and non-intersection areas.

An even layer of polysilicon is deposited to fill trench 54. When the polysilicon etched back, the polysilicon remains at least to a level substantially even with or slightly above the top of trench 54 in the intersection and non-intersection areas because both areas have substantially the same width across the trench. As a result, the polysilicon material in and around intersections 16 is devoid of any depressions or reduction in thickness. The polysilicon material over intersection 16 is at least substantially level with or slightly above the top of trench 54 over the entire surface area of intersection 16.

A variety of patterns can be used to narrow the width of trench 54 in and around intersection 16. The narrowing pattern can be gradual and rounded, abrupt and pointed, or some combination thereof or other pattern that reduces the effective width of trench 54 in and around intersection 16 to be substantially equal to the width of the non-intersection areas of the trench which in turn avoids depressions in gate region 30.

A person skilled in the art will recognize that changes can be made in form and detail, and equivalents may be substituted, for elements of the invention without departing from the scope and spirit of the invention. The present description is therefore considered in all respects to be illustrative and not restrictive, the scope of the invention being determined by the following claims and their equivalents as supported by the above disclosure and drawings.

1. A method of manufacturing a closed cell trench semiconductor device, comprising:
forming a drain region;
disposing an epitaxial region over the drain region;
forming a body region over the epitaxial region;
forming a trench in first and second directions through the body region and extending into the epitaxial region, wherein the trench in the first direction and the trench in the second direction cross to form an intersection;
depositing a conductive material in the trench; and
forming a protective layer over the intersection to inhibit removal of the conductive material from the trench in and around the intersection.

2. The method of claim 1 further including the step of forming a source region in the body region adjacent to the trench.

3. The method of claim 1 further including the step of forming an oxide layer within the trench prior to depositing the conductive material in the trench.

4. The method of claim 1 wherein the trench in the first direction is substantially perpendicular to the trench in the second direction.

5. The method of claim 1 wherein the conductive material comprises polysilicon.

6. The method of claim 1 wherein the protective layer comprises photoresist.

7. The method of claim 1, wherein the drain region and the epitaxial region are doped with a first type of semiconductor material.

8. The method of claim 7, wherein the body region is doped with a second type of semiconductor material.

9. The method of claim 1, wherein the semiconductor device is a power MOSFET.

10. A method of manufacturing a semiconductor device, comprising:
forming a drain region;
depositing an epitaxial region over the drain region;
forming a body region over the epitaxial region;
forming a trench in first and second directions through the body region and extending into the epitaxial region, wherein the trench in the first direction and the trench in the second direction cross to form an intersection;
depositing a conductive material in the trench; and
removing a portion of the conductive material without forming a depression in and around the intersection of the trench.

11. The method of claim 10 further including the step of forming a protective layer over the intersection to inhibit removal of the conductive material from the trench.

12. The method of claim 11 wherein the protective layer comprises photoresist.

13. The method of claim 10 further including forming a thicker portion of conductive material over the intersection than over non-intersection areas of the trench.

14. The method of claim 10 further including narrowing a width of the trench in and around the intersection.

15. The method of claim 10 wherein the trench in the first direction is substantially perpendicular to the trench in the second direction.

16. The method of claim 10 wherein the conductive material comprises polysilicon.

17. The method of claim 10 wherein the conductive material comprises metal silicide.

18. The method of claim 10, wherein the semiconductor device is a power MOSFET.

19. In a semiconductor device comprising a trench running first and second directions through a body region, a method of inhibiting removal of conductive material from an intersection formed by the trench running in the first direction crossing the trench running in the second direction, the method comprising the steps of:
depositing the conductive material in the trench; and
forming a protective layer over the intersection to inhibit removal of the conductive material from the trench in and around the intersection.

20. The method of claim 19 wherein the trench in the first direction is substantially perpendicular to the trench in the second direction.

21. The method of claim 19 wherein the conductive material comprises polysilicon.

22. The method of claim 19 wherein the protective layer comprises photoresist.

23. The method of claim 19, wherein the semiconductor device is a power MOSFET.

24. A method of manufacturing a semiconductor device, comprising:
forming a drain region;
depositing an epitaxial region over the drain region;
forming a body region over the epitaxial region;
forming a trench in first and second directions through the body region and extending into the epitaxial region, wherein the trench in the first direction and the trench in the second direction cross to form an intersection;
narrowing a width of the trench in and around the intersection; and
depositing a conductive material in the trench.

25. The method of claim 24 wherein the width of the trench in and around the intersection is made substantially the same as a width of the trench across non-intersection areas.

26. A semiconductor device, comprising:
a drain region;
an epitaxial region disposed over the drain region;
a body region disposed over the epitaxial region;
a trench running in first and second directions through the body region and extending into the epitaxial region, wherein the trench in the first direction and the trench in the second direction cross to form an intersection;
a conductive material deposited in the trench, wherein a protective layer formed over the intersection inhibits removal of the conductive material from the trench in and around the intersection.

27. The semiconductor device of claim 26 further including:
a source region formed in the body region adjacent to the trench; and
an oxide layer within the trench.

28. The semiconductor device of claim 26 wherein the trench in the first direction is substantially perpendicular to the trench in the second direction.

29. The semiconductor device of claim 26 wherein the conductive material comprises polysilicon and the protective layer comprises photoresist.

30. The semiconductor device of claim 26, wherein the semiconductor device is a power MOSFET.
